(19) United States
(12) Patent Application Publication
(10) Pub. No.: US 2014/0363911 A1
(43) Pub. Date: Dec. 11, 2014

(54) METHOD FOR PRODUCING ORGANIC EL DISPLAY PANEL

(71) Applicant: Panasonic Corporation, Osaka (JP)

(72) Inventor: Yumeji Takashige, Osaka (JP)

(73) Assignee: PANASONIC CORPORATION, Osaka (JP)

(21) Appl. No.: 14/362,638

(22) PCT Filed: Dec. 14, 2012
(86) PCT No.: PCT/JP2012/008030

§ 371 Date: Jun. 4, 2014

(30) Foreign Application Priority Data
Dec. 15, 2011 (JP) 2011-274415

(51) Int. Cl. H01L 51/56

(52) U.S. Cl. CPC H01L 51/56
USPC 438/34

(57) ABSTRACT

A manufacturing method of an organic EL display panel includes: preparing G, R, and B inks that each include a solvent and respectively include G, R, and B organic light-emitting materials differing from each other in terms of light-emitting wavelength; applying the G ink to G subpixel regions on a substrate; applying the R ink to R subpixel regions; and applying the B ink to B subpixel regions. The R and B subpixel regions are each adjacent to a corresponding one of the G subpixel regions on both sides thereof. The G ink has a lower viscosity than the R and B inks. After application of the R and B inks is started, application of the G ink is started.

### TECHNICAL FIELD

The present invention relates to a manufacturing method of an organic EL display panel including a forming process of a light-emitting layer by a printing method such as an ink jet method.

### BACKGROUND ART

Recently, researches and developments have been promoted on organic electroluminescence elements (hereinafter, referred to just as organic EL elements) which are current-driven light-emitting elements and rely on electroluminescence phenomenon of organic fluorescent materials. Also, as display devices employing organic EL elements, there have been widely used organic EL display panels having a configuration in which organic EL elements are arranged on a substrate. Organic EL elements included in an organic EL display panel are configured from a TFT (thin film transistor) substrate, anodes made of metal such as Al, light-emitting layers made of an organic light-emitting material, and a cathode made of a transparent material such as ITO (Indium Tin Oxide) that are laminated in respective orders. Also, the organic EL elements each further include a hole injection layer, a hole transport layer, an electron injection layer, an electron transport layer, a sealing layer, and so on as necessary.

Light emitting layers included in an organic EL display panel are formed by a vacuum evaporation method, or a printing method according to which an organic material ink, which results from dissolving a tiny amount of an organic light-emitting material in a solvent, is applied by an ink jet. The printing method allows formation of light-emitting layers with use of a manufacturing device simplifier than the vacuum evaporation method. Also, a large size organic EL display panel is formed by the printing method with use of a manufacturing device that is simplifier than in the vacuum evaporation method, and accordingly is of more advantage than the vacuum evaporation method in terms of manufacturing cost for example.

According to a conventional method of forming light-emitting layers by the printing method with use of an ink jet, a barrier rib (referred to also a as bank) that is made of a material including a liquid repellent component is formed on a substrate, and an organic material ink, which results from dissolving a tiny amount of an organic light-emitting material in a solvent, is applied to each of subpixel regions surrounded by the barrier rib (see Patent Literatures 1 and 2). The adjacent light-emitting layers differ from each other in terms of luminescent color of R (Red), G (Green), and B (Blue) colors. Also, the light-emitting layers differ in terms of material for each luminescent color.

### CITATION LIST

### Patent Literature

[Patent Literature 1]

Japanese Patent Application Publication No. 2002-222695

[Patent Literature 2]

Japanese Patent Application Publication No. 2011-18632

### SUMMARY OF INVENTION

### Technical Problem

However, the present inventors demonstrated by experiments that formation of an organic EL display panel by the printing method results in light-emitting layers having cross-sectional shapes that vary between subpixel regions, and this might cause uneven luminance.

The present invention aims to suppress uneven luminance in an organic EL display panel that is manufactured by the printing method.

### Solution to Problem

One aspect of the present invention provides a manufacturing method of an organic EL display panel comprising: preparing a first ink including a first organic light-emitting material and a solvent; preparing a second ink including a second organic light-emitting material and a solvent, the second organic light-emitting material differing from the first organic light-emitting material in terms of light-emitting wavelength; preparing a third ink including a third organic light-emitting material and a solvent, the third organic light-emitting material differing from the first organic light-emitting material and the second organic light-emitting material in terms of light-emitting wavelength; applying the first ink to first subpixel regions on a substrate; applying the second ink to second subpixel regions that are each adjacent to a corresponding one of the first subpixel regions; and applying the third ink to third subpixel regions that are each adjacent to a corresponding one of the first subpixel regions on an opposite side of the first subpixel region relative to a corresponding one of the second subpixel regions, wherein the first ink has a lower viscosity than the second ink and the third ink, and after application of the second ink and the third ink is started, application of the first ink is started.

### Advantageous Effects of Invention

According to the manufacturing method of the organic EL display panel relating to the above aspect, it is possible to suppress an influence exercised by difference in concentration of solvent atmosphere during a time period from when application of the first ink is started to when drying of the first ink is completed. The difference in concentration of solvent atmosphere occurs between respective solvents which are evaporated from the second and third subpixel regions, which are adjacent to each of the first subpixel regions on the both sides thereof, and is hereinafter referred to for example as difference in solvent atmosphere on the both sides. For example, at the start time of application of the first ink, the second and third inks have been already applied respectively to the second and third subpixel regions which are adjacent to the first subpixel region on the both sides. This suppresses difference in solvent atmosphere between the second and third subpixel regions, which are adjacent to the first subpixel region on the both sides, compared with the case where an ink has been already applied to only one of the second and third subpixel regions at the start time of application of the first ink. Since the difference in solvent atmosphere on the both sides of the first subpixel region is suppressed, it is also possible to suppress variation in the difference in solvent atmosphere on the both sides between the first subpixel regions which are positioned in different positions in the organic EL display panel.

By the way, during a time period between start of application of the first ink and completion of drying of the first ink, an evaporation speed of the solvent included in the first ink differs within the first subpixel region due to the difference in solvent atmosphere on the both sides of the first subpixel region. The difference in evaporation speed causes convection current. Accordingly, in the case where variation occurs in the difference in solvent atmosphere on the both sides between the first subpixel regions which are positioned in different positions in the organic EL display panel, difference might occur in convection current of the solvent included in the first ink between the first subpixel regions. The difference in convection current of the solvent included in the first ink causes difference in distribution of solute included in the first ink between the first subpixel regions, which are positioned in different positions in the organic EL display panel. As a result, difference might occur in shape between light-emitting layers resulting from applying the first ink.

Therefore, according to the manufacturing method of the organic EL display panel relating to the above one aspect, by suppressing variation in the difference in solvent atmosphere on the both sides between the first subpixel regions which are positioned in different positions, it is possible to suppress variation in shape of light-emitting layers which are formed by applying the first ink.

### BRIEF DESCRIPTION OF DRAWINGS

FIG. 1 is a cross-sectional view showing an organic EL display panel relating to Embodiment 1.

FIG. 2 is a top view showing the organic EL display panel shown in FIG. 1 from which an electron injection layer, a cathode, and a sealing layer are removed.

FIG. 3A to FIG. 3D are cross-sectional views showing a manufacturing process of the organic EL display panel shown in FIG. 1.

FIG. 4A shows operations of an ink jet head at the time of manufacturing of the organic EL display panel shown in FIG. 1, and FIG. 4B is a top view showing the organic EL display panel 1 shown in FIG. 1 at the time of manufacturing thereof.

FIG. 5A to FIG. 5F are cross-sectional views showing the details of a process of forming light-emitting layers in the manufacturing process shown in FIG. 3A to FIG. 3D.

FIG. 6A to FIG. 6C are top views showing the process of forming light-emitting layers shown in FIG. 5A to FIG. 5F.

FIG. 7 is a time chart showing the process of forming light-emitting layers shown in FIG. 5A to FIG. 5F.

FIG. 8A to FIG. 8C each show a shape of an upper surface of a different light-emitting layer in a conventional organic EL display panel, and FIG. 8D and FIG. 8F each show a shape of an upper surface of a different light-emitting layer in the organic EL display panel shown in FIG. 1.

FIG. 9A to FIG. 9D explain the manufacturing process of the organic EL display panel shown in FIG. 1.

FIG. 10A to FIG. 10C explain a manufacturing process with use of an organic material ink having a low viscosity.

FIG. 11A to FIG. 11C explain a manufacturing process with use of an organic material ink having a high viscosity.

FIG. 12A to FIG. 12E are cross-sectional views showing the details of a process of forming light-emitting layers in the manufacturing process shown in FIG. 3A to FIG. 3D.

FIG. 13A and FIG. 13B are top views showing the process of forming light-emitting layers shown in FIG. 12A to FIG. 12E.

FIG. 14 is a time chart showing the process of forming light-emitting layers shown in FIG. 12A to FIG. 12E.

FIG. 15A and FIG. 15B are time charts showing a manufacturing process of an organic EL display panel relating to Modification.

FIG. 16 is a schematic block diagram showing the outline configuration of the manufacturing process of the organic EL display panel shown in FIG. 1.

FIG. 17 is an appearance diagram showing an organic EL display device including the organic EL display panel shown in FIG. 1.

### DESCRIPTION OF EMBODIMENTS

[Process by which One Aspect of the Present Invention was Achieved]

Before concretely describing one aspect of the present invention, the following describes the process by which the aspect of the present invention was achieved.

In the case where light-emitting layers are formed by an evaporation method, R, G, and B organic light-emitting materials are considered to be evaporated in this order for example. This is because it is considered that, in terms of operating life, R organic EL elements are the longest, followed in order by G and B organic EL elements, and it is advantageous to start forming light-emitting layers with R light-emitting layers, which have the longest operating life. The following describes advantages that formation of light-emitting layers is performed in descending order of length of operating life.

Manufacturing of organic EL elements is completed for example by forming light-emitting layers on a TFT substrate, and sealing the light-emitting layers by a cathode, a sealing layer, and so on. During a time period between completion of formation of sealing of the light-emitting layers and completion of sealing of the light-emitting layers, the light-emitting layers are subject to deterioration because moisture, oxygen, and so on are easy to reach the light-emitting layers. Accordingly, the longer the time period between completion of formation of the light-emitting layers and completion of sealing of the light-emitting layers is, the more possibility of deterioration of the light-emitting layers increases. By starting formation of light-emitting layers with the R light-emitting layers, which have the longest operating life, light-emitting layers which have shorter operating life have less possibility of deterioration. Accordingly, compared with the case where light-emitting layers which have shorter operating life have more possibility of deterioration, it is possible to suppress a operating life of the entire organic EL display panel.

By the way, the present inventors tested to manufacture an organic EL display panel by a printing method using an ink jet according to which light-emitting layers are formed by a manufacturing device that is more simplified than in the vacuum evaporation method. However, any research and development have not yet been performed on an application order of organic light-emitting materials in the printing method. For this reason, application of organic light-emitting materials is considered to be performed in the same order as that in the above evaporation method. Accordingly, in the same manner as in the evaporation method, the present inventors tested to apply organic material inks in order of decreasing operating life of the light-emitting layers corresponding to the organic material inks. In other words, the present inventors tested to use R, G, and B organic material inks to form R, G, and B light-emitting layers, by applying the R, G, and B organic material inks in respective orders, and then performing forced drying processing such as bake drying processing, reduced-pressure drying processing, or the like on the R, G, and B organic material inks. However, the present inventors proved that this manufacturing method results in variation in cross-sectional shape of the light-emitting layers between subpixel regions, and might cause uneven luminance.

Furthermore, after checking a relationship between uneven luminance and viscosity of organic material ink which are materials of light-emitting layers, the present inventors proved that a large uneven luminance occurs especially in light-emitting layers which are formed using an organic material ink having a comparatively low viscosity.

There occurs variation in cross-sectional shape of the light-emitting layers, which are formed using an organic material ink having a comparatively low viscosity, because an organic material ink having a low viscosity is larger in liquidity of solvent than an organic material ink having a high viscosity, and is more subject to an influence exercised by solvent atmosphere than the organic material ink having a high viscosity.

The inventors focused on this point, and conceived an idea of determining an application order of organic material inks based on a viscosity of the organic material inks. Then, the present inventors achieved results that it is possible to suppress variation in cross-sectional shape of light-emitting layers between subpixel regions even if the light-emitting layers are formed using an organic material ink having a low viscosity. The one aspect of the present invention was achieved through the process described above.

### [Outline of One Aspect of the Present Invention]

One aspect of the present invention provides a manufacturing method of an organic EL display panel comprising: preparing a first ink including a first organic light-emitting material and a solvent; preparing a second ink including a second organic light-emitting material and a solvent, the second organic light-emitting material differing from the first organic light-emitting material in terms of light-emitting wavelength; preparing a third ink including a third organic light-emitting material and a solvent, the third organic light-emitting material differing from the first organic light-emitting material and the second organic light-emitting material in terms of light-emitting wavelength; applying the first ink to first subpixel regions on a substrate; applying the second ink to second subpixel regions that are each adjacent to a corresponding one of the first subpixel regions; and applying the third ink to third subpixel regions that are each adjacent to a corresponding one of the first subpixel regions on an opposite side of the first subpixel region relative to a corresponding one of the second subpixel regions, wherein the first ink has a lower viscosity than the second ink and the third ink, and after application of the second ink and the third ink is started, application of the first ink is started.

According to the manufacturing method of the organic EL display panel relating to the one aspect of the present invention, it is possible to suppress an influence exercised by difference in solvent atmosphere between the second and third subpixel regions adjacent to each of the first sub pixel regions on the both sides thereof during a time period between start of application of the first ink and completion of drying of the first ink, which has a low viscosity. For example, when application of the first ink having a low viscosity to the first subpixel region is started, an ink has been already applied to the second and third subpixel regions which are adjacent to the first subpixel region. This suppresses difference in solvent atmosphere between the second and third subpixel regions compared with the case where an ink has been already applied to only one of the second and third subpixel regions which are adjacent to the first subpixel region at the start time of application of the first ink. Therefore, according to the above manufacturing method, compared with the case where an ink exists in only one of the second and third subpixel regions at the start time of application of the first ink, which are adjacent to the first subpixel region, it is possible to suppress difference in solvent atmosphere on the both sides between the first subpixel regions which are positioned in different positions in the organic EL display panel. As a result, it is possible to suppress variation in shape of light-emitting layers which results from applying the first ink and are positioned in different positions in the organic EL display panel.

Also, the manufacturing method of the organic EL display panel relating to the one aspect of the present invention may further comprise drying the second ink, after the applying the second ink; and drying the third ink, after the applying the third ink, wherein after drying of the second ink and the third ink is started, application of the first ink may be started.

Also, the manufacturing method of the organic EL display panel relating to the one aspect of the present invention may further comprise drying the second ink, after the applying the second ink; and drying the third ink, after the applying the third ink, wherein after drying of the second ink and the third ink is completed, application of the first ink may be started.

Also, the manufacturing method of the organic EL display panel relating to the one aspect of the present invention may further comprise drying the first ink through forced drying processing, after the applying the first ink; drying the second ink through forced drying processing, after the applying the second ink; and drying the third ink through forced drying processing, after the applying the third ink, wherein a natural drying time period of the first ink may be longer than a natural drying time period of each of the second ink and the third ink, the natural drying time period being a time period from when application is completed to when forced drying processing is started.

Also, according to the manufacturing method of the organic EL display panel relating to the one aspect of the present invention, after application of the second ink and the third ink is completed, application of the first ink may be started, and after application of the first ink is completed, drying of the first ink, the second ink, and the third ink may be collectively performed through forced drying processing.

Also, the manufacturing method of the organic EL display panel relating to the one aspect of the present invention may further comprise drying the second ink through forced drying processing, after the applying the second ink; and drying the third ink through forced drying processing, after the applying the third ink, wherein after drying of the second ink and the third ink is completed, application of the first ink may be started.

Also, the manufacturing method of the organic EL display panel relating to the one aspect of the present invention may further comprise drying the first ink through natural drying processing, after the applying the first ink.

Also, according to the manufacturing method of the organic EL display panel relating to the one aspect of the present invention, application of one of the second ink and the third ink that has a longer operating life than the other may be started earlier than the other.

Also, according to the manufacturing method of the organic EL display panel relating to the one aspect of the present invention, application of one of the second ink and the third ink that has a lower viscosity than the other may be started earlier than the other.

Also, according to the manufacturing method of the organic EL display panel relating to the one aspect of the present invention, a natural drying time period of the one of the second ink and the third ink that has a lower viscosity than the other may be longer than a natural drying time period of the other, the natural drying time period being a time period from when application is completed to when forced drying processing is started.

### Embodiment 1

### 1. Overall Configuration

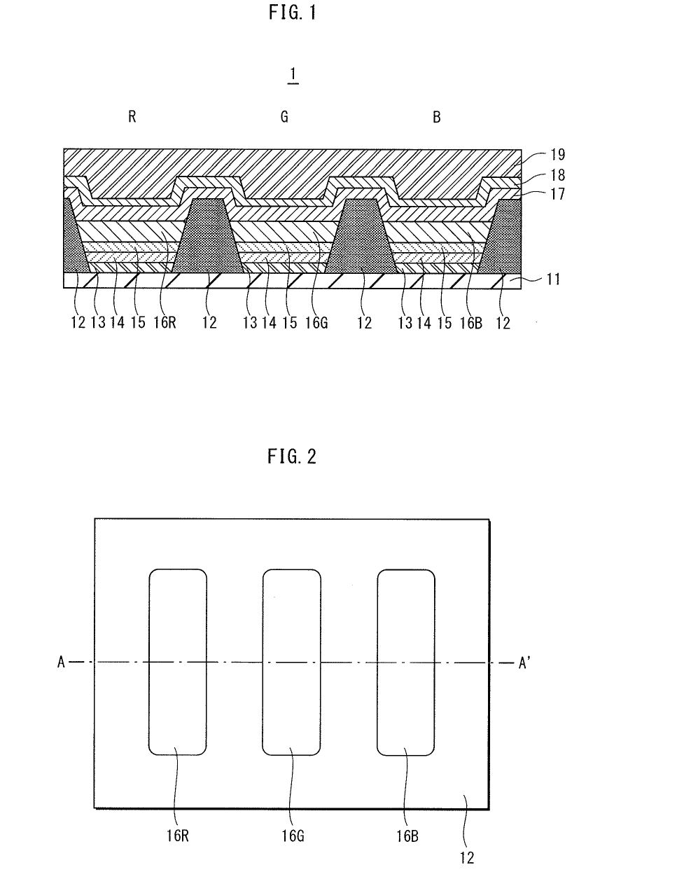

The following describes embodiments in detail with reference to the drawings. FIG. 1 is a cross-sectional view showing an organic EL display panel 1 relating to Embodiment 1. The organic EL display panel 1 includes a TFT (thin film transistor) substrate 11 and a barrier rib layer 12 that is formed on the TFT substrate 11. The TFT substrate 11 is constituted from a glass substrate, a TFT, a planarizing layer, and so on. In order to light the organic EL display panel 1, the planarizing layer that is provided between the glass substrate and anodes 13 reduces roughness of the TFT, which is provided on the glass substrate. Note that the TFT and the planarizing layer have known configurations, and accordingly illustration thereof is omitted here. The barrier rib layer 12 has a film thickness of approximately 1 um, and has a forward tapered cross section.

In a subpixel region that is positioned in each adjacent two portions of the barrier rib layer 12, the anode 13, a hole injection layer 14, an IL layer (interlayer) 15, and one of light-emitting layers 16R, 16G, and 16B are laminated. The anodes 13 are made of metal such as Al. The light-emitting layers 16R, 16G, and 16B are each made of an organic material, and hereinafter referred to collectively as light-emitting layers 16 when distinction therebetween is unnecessary. Furthermore, an electron injection layer 17, a cathode 18, and a sealing layer 19 are laminated in respective orders so as to cover the barrier rib layer 12 and the light-emitting layers 16. The cathode 18 is made of a transparent material such as ITO. The sealing layer 19 is made of a light transmissive material such as SiN and SiON. The organic EL display panel 1 includes pixels that are each constituted from a combination of three R, G, and B subpixels. Also, the R, G, and B subpixel regions differ in luminescent color because of difference in material between the light-emitting layers 16R, 16G, and 16B.

FIG. 2 is a top view of the organic EL display panel 1 from which the electron injection layer 17, the cathode 18, and the sealing layer 19 are removed, where the barrier rib layer 12 and the light-emitting layers 16 are illustrated. A cross-sectional view taken along line A-A′ in FIG. 2 is equivalent to FIG. 1. Note that only one pixel (three subpixels) of the organic EL display panel 1 is illustrated in FIG. 1 and FIG. 2. The barrier rib layer 12 surrounds each of the light-emitting layers 16. Also, respective regions indicated as the light-emitting layers 16R, 16G, and 16B in FIG. 2 each represent a subpixel region. In the case where a general 20-inch organic EL display panel has 1280×768 pixels arranged in equal intervals, subpixel regions each have a size of approximately 64 um×234 um.

In the present embodiment, respective light-emitting layers emitting light of the R, G, and B colors are referred to as an R light-emitting layer, a G light-emitting layer, and a B light-emitting layer. Also, respective organic material inks emitting light of the R, G, and B colors are referred to as an R organic material ink RI, a G organic material ink GI, and a B organic material ink BI.

### 2. Manufacturing Process of Organic EL Display Panel 1

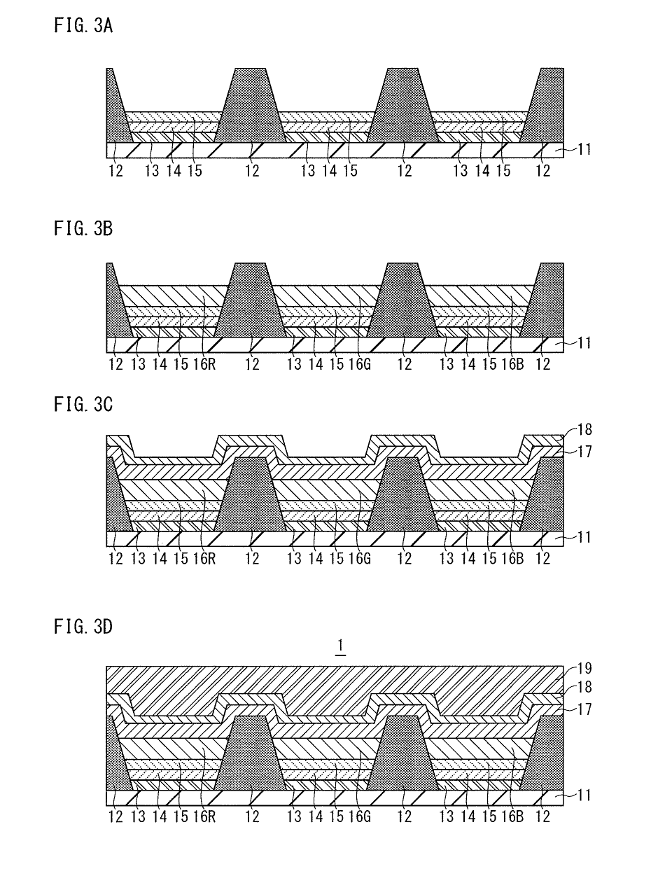

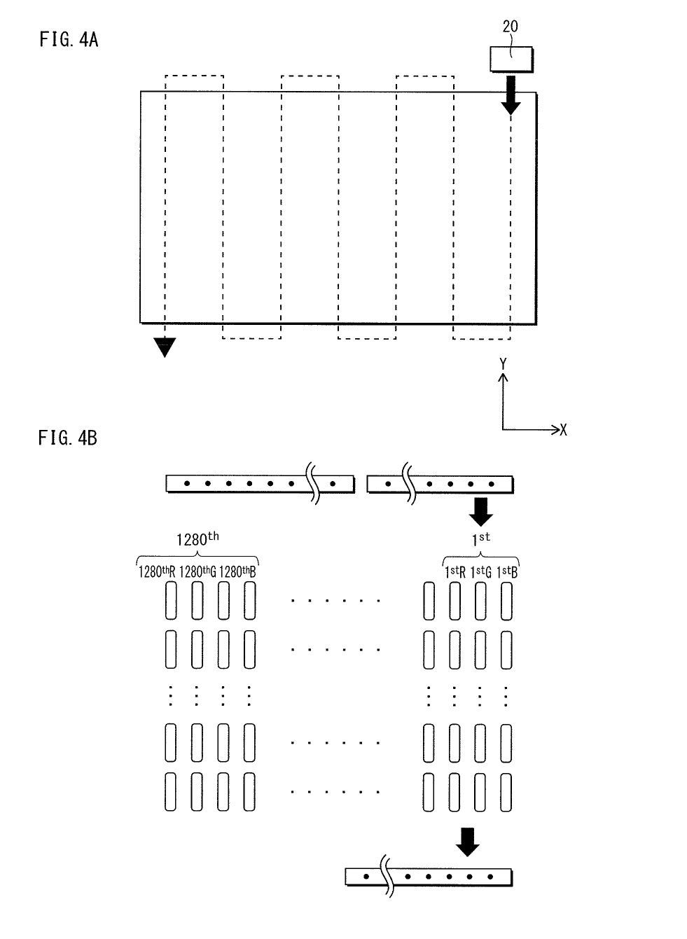

The following describes a manufacturing process of the organic EL display panel. Firstly, the entire process is described with reference to FIG. 3A to FIG. 3D, and then a process of forming light-emitting layers is described in detail with reference to FIG. 4A to FIG. 7.

As shown in FIG. 3A, a substrate is prepared on which a TFT substrate 11, a barrier rib layer 12, anodes 13, hole injection layers 14, and IL layers 15 are laminated.

As shown in FIG. 3B, an organic material ink, which is a material of light-emitting layers 16, is applied to each of subpixel regions surrounded by the barrier rib layer 12 by a printing method using an ink jet. The applied organic material ink undergoes natural drying processing, and then undergoes forced drying processing such as reduced-pressure drying processing and bake drying processing. As a result, the light-emitting layers 16 are obtained.

As shown in FIG. 3C, an electron injection layer 17 and a cathode 18 are formed so as to cover the barrier rib layer 12 and the light-emitting layers 16.

As shown in FIG. 3D, a sealing layer 19 is formed on the cathode 18. This completes an organic EL display panel 1.

Note that the electron injection layer 17, the cathode 18, and the sealing layer 19 are formed by general members and formation techniques that are used in a known art relating to organic light-emitting devices.

The organic EL display panel 1 is manufactured through the above processes.

### 3. Details of Process of Forming Light Emitting Layers

### (Operations of Ink Jet Head)

The following describes in detail the process of forming the light-emitting layers 16, especially operations of the ink jet head.

In the present embodiment, an ink jet device includes an ink jet head 20 having three types of ink discharging nozzles. As shown in FIG. 4A, the ink jet device performing scanning by the ink jet head 20 to discharge and apply organic material inks to the subpixel regions from the nozzle while controlling the positional relationship between the nozzles and the substrate. Note that the ink jet head 20 is for example a piezo ink jet head that discharges an ink by deforming piezo elements. Also, a multipath printing method is used according to which an organic material ink is applied by repeating plural times of an operation of scanning in the Y-direction and then moving in the X-direction by the ink jet head 20.

The following describes the printing method in further detail. The ink jet head 20 has print heads corresponding to the luminescent colors, namely an R print head, a G print head, and a B print head. The R, G, and B print heads each discharge droplets of an organic material ink such that the nozzles one-to-one correspond to the subpixels. The droplets are landed on a desired subpixel region, and the droplets are dried. As a result, light-emitting layers 16 are formed. Here, the R, G, and B print heads used in the present embodiment each have 64 nozzles. The organic material ink is applied to the entire organic EL display panel 1 for each of all the R, G, and B colors by repeating scanning 20 times from the 1st scanning to the 20th scanning while moving the print head to a part where printing has not been yet performed. As a result, the light-emitting layers 16 for the entire organic EL display panel 1 is completed.

Conditions of ink viscosity adjustment and ink dropping on subpixel regions are set as follows: a G organic material ink of 72 pl, which has a comparatively low viscosity of approximately 5 mP, is dropped for each subpixel; an R organic material ink of 72 pl, which has a viscosity of approximately 15 mPas higher than the G organic material ink, is dropped for each subpixel; and a B organic material ink of 70 pl, which has a viscosity of approximately 12 mPas higher than the G organic material ink, is dropped for each subpixel. An organic solvent having a boiling temperature of approximately 200 degree C. is used as a solvent for all the organic material inks.

### (Details of Process of Forming Light-Emitting Layers)

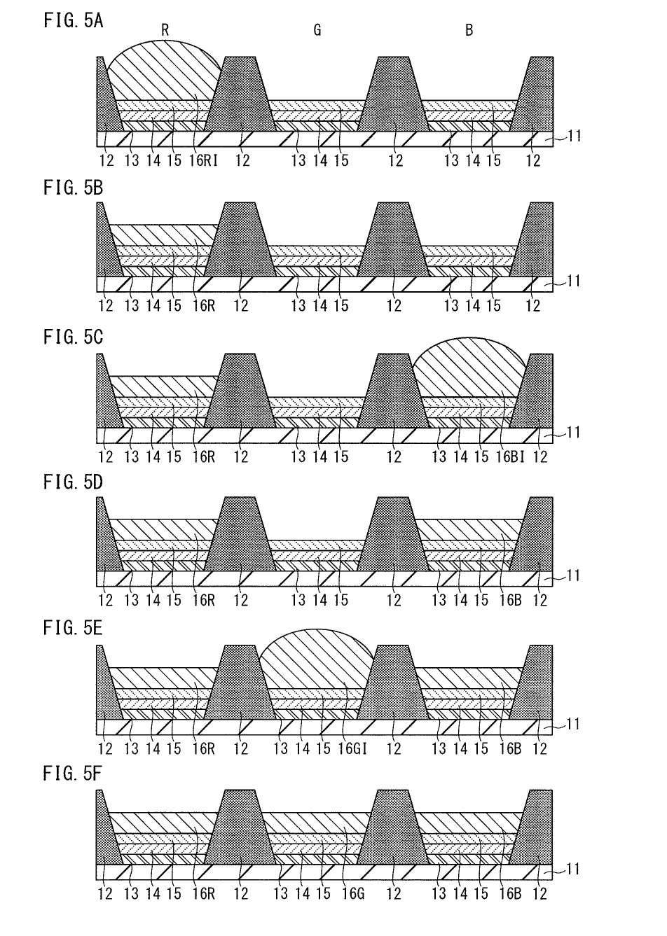

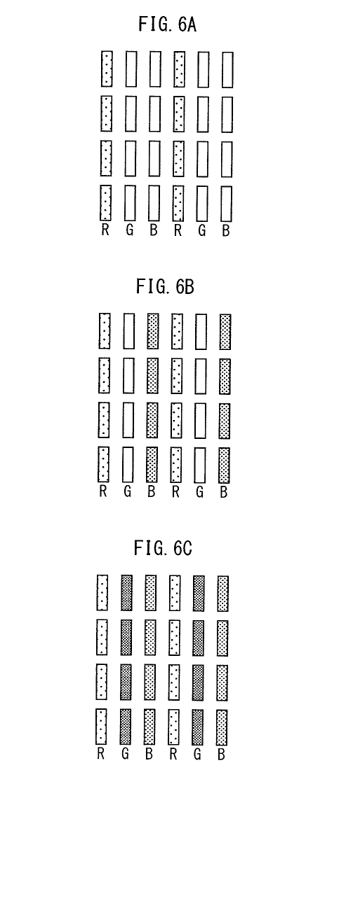

FIG. 5A to FIG. 5F are cross-sectional views showing the details of the process of forming light-emitting layers in the manufacturing process shown in FIG. 3A to FIG. 3D. FIG. 6A to FIG. 6C are top views showing the process of forming light-emitting layers shown in FIG. 5A to FIG. 5F.

As shown in FIG. 5A, an R organic material ink 16RI is applied to each of R subpixel regions by the ink jet method.

Next, as shown in FIG. 5B, R light-emitting layers 16R are formed. Specifically, the R organic material ink 16RI is applied, and then the R organic material ink 16RI undergoes reduced-pressure drying processing at 0.5 Pa for 20 minutes. As a result, an R light-emitting layer 16R is formed in each of the R subpixel regions. A solvent for the R organic material ink 16RI is completely dried from the R subpixels regions through natural drying processing and reduced-pressure drying processing. Alternatively, forced drying processing may be performed through heated-air drying processing such as bake drying processing instead of reduced-pressure drying processing. FIG. 6A is an overhead view of the state shown in FIG. 5B.

As shown in FIG. 5C, after the R light-emitting layers 16R are formed, a B organic material ink 16BI is applied to each of B subpixel regions by the ink jet method.

Next, as shown in FIG. 5D, B light-emitting layers 16B are formed. Specifically, a B organic material ink 16BI is applied to each of all the B subpixel regions on the organic EL display panel 1, and then the B organic material ink 16BI undergoes reduced-pressure drying processing at 0.5 Pa for 20 minutes. FIG. 6B is an overhead view of the state shown in FIG. 5D. Note that, during a time period between start of application and completion of application of each of the R organic material ink 16RI and the B organic material ink 16BI, the B ink, which has been applied to the subpixel regions, is spontaneously dried.

As shown in FIG. 5E, after the B light-emitting layers 16B are formed, a G organic material ink 16GI is applied to each of G subpixel regions by the ink jet method. At the start time of application of the G organic material ink 16GI, the R light-emitting layer 16R and the B light-emitting layer 16B have been already formed respectively in the R and B subpixel regions which are adjacent to each of the G subpixel regions on both sides thereof. This suppresses difference in solvent atmosphere between the R and B subpixel regions which are adjacent to the G subpixel region on the both sides, compared with the case where an organic material ink which has not been yet dried remains in only one of the R and B subpixel regions at the start time of application of the G organic material ink 16GI.

Next, as shown in FIG. 5F, a G light-emitting layer 16G is formed. Specifically, after the G organic material ink 16GI is applied to all the G subpixel regions on the entire organic EL display panel 1, a stand-by time period is given without performing forced drying processing until the solvent applied to each of all the G subpixel regions is dried by leaving the substrate unattended. Here, giving a stand-by time period for drying without performing forced drying processing such as reduced-pressure drying processing and bake drying processing is referred to as natural drying processing. In the present embodiment, natural drying processing is performed for a stand-by time period of approximately 20 minutes to 30 minutes until the solvent applied to all the G subpixel regions on the organic EL display panel 1 is dried. Then, the G organic material ink 16GI undergoes reduced-pressure drying processing at 0.5 Pa for 20 minutes. FIG. 6C is an overhead view of the state shown in FIG. 5F.

Then, the entire surface of the organic EL display panel 1 is baked at 130 degrees C. under N₂ atmosphere for 10 minutes. This completes formation of the light-emitting layers 16.

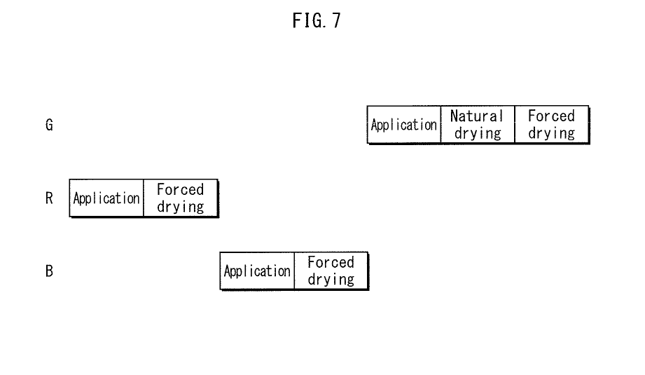

The following describes the above process of forming the light-emitting layers 16 in chronological order. FIG. 7 is a time chart showing the manufacturing process of the organic EL display panel 1. Processes indicated by letters R, G, and B in FIG. 7 represent processes performed on the R, G, and B subpixel regions, respectively.

Firstly, the R organic material ink 16RI is applied, and then undergoes forced drying processing by reduced-pressure drying processing. As a result, the light-emitting layers 16R are formed. Next, the B organic material ink 16BI is applied, and then undergoes forced drying processing by reduced-pressure drying processing. As a result, the B light-emitting layers 16B are formed. Finally, the G organic material ink 16GI is applied, and then undergoes natural drying processing, and then undergoes forced drying processing by reduced-pressure drying processing. As a result, the G light-emitting layers 16G are formed. As described above, at the start time of application of the G organic material ink 16GI, the R light-emitting layer 16R and the B light-emitting layer 16B have been already formed respectively in the R and B subpixel regions which are adjacent to each of the G subpixel regions on both sides thereof. Therefore, no solvent remains which has not been yet dried in the R and B subpixel regions which are adjacent to the G subpixel region on the both sides. Note that at the start time of the G organic material ink 16GI, the G organic material ink 16GI has been sufficiently dried, and therefore the shape of the light-emitting layers 16G has been determined.

### 5. Effects

### (5-1) Observation Results of Cross-Sectional Shape of Light-Emitting Layers

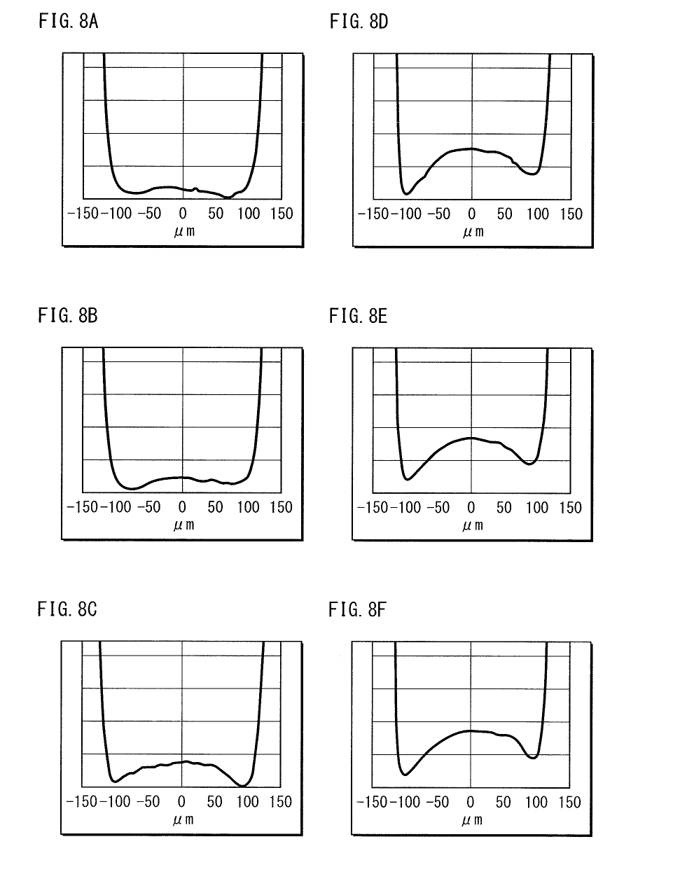

FIG. 8A to FIG. 8C each show a shape of an upper surface of a different G light-emitting layer 16G of an organic EL display panel 1 relating to a comparative example. FIG. 8D to FIG. 8F each show a shape of an upper surface of a different G light-emitting layer 16G of the organic EL display panel 1 relating to the present embodiment. Specifically, the ink jet head 20 performs an operation of scanning and application 20 times for each of the R organic material ink 16RI, the G organic material ink 16GI, and the organic material ink 16BI (hereinafter, when distinction is unnecessary, these three types of inks are referred to collectively organic material ink 16I). Then, the shape of the upper surface of each of the G light-emitting layers 16G resulting from drying the organic material ink 16I is evaluated by AFM (Atomic Force Microscope).

In the comparative example in which results shown in FIG. 8A to FIG. 8C are obtained, in the case where the R organic material ink is the longest, followed in order by the G and B organic material inks in terms of operating life for example, application of the respective R, G, and B organic material inks 16RI, 16GI, and 16BI is performed in respective orders. Then, the respective R, G, and B organic material inks 16RI, 16GI, and 16BI collectively undergo reduced-pressure drying processing. Application is performed in this order in order to reduce a possibility that if the organic EL display panel 1 is left unattended for a long time period under an atmosphere in which application is completed, an organic material ink of a specific luminescent color deteriorates soon. In other words, since the B light-emitting layer 16B has the shortest operating life, the shortest time period between application and sealing is set for the B organic material ink 16BI. This suppresses deterioration of the whole operating life of the light-emitting layers 16.

In the results in the comparative example shown in FIG. 8A to FIG. 8C, there is variation in shape of the upper surfaces of the light-emitting layers 16G in the three different subpixel regions. Specifically, respective uppermost parts of the upper surfaces of the G light-emitting layers 16G shown in FIG. 8A to FIG. 8C are −20 μm, 0 μm, and 5 μm, respectively. Also, respective lowermost parts of the upper surfaces of the G light-emitting layers 16G shown in FIG. 8A to FIG. 8C are 70 μm, −75 μm, and 95 μm, respectively.

In the results in the present embodiment shown in FIG. 8D to FIG. 8F, on the other hand, there is no variation in shape of the upper surfaces of the light-emitting layers 16G in the three different subpixel regions. Specifically, respective uppermost parts of the upper surfaces of the G light-emitting layers 16G shown in FIG. 8D to FIG. 8F are each 0 μm. Also, respective lowermost parts of the upper surfaces of the G light-emitting layers 16G shown in FIG. 8D to FIG. 8F are each −100 μm. Note that further uniformization of the cross-sectional shape of the light-emitting layers is realized by appropriately selecting a material, water repellency, an inclination angle of lateral surfaces, and so on of the bank.

### (5-2-1) Consideration on Application Order

The following considers in detail the effects of the application order of organic material inks in the present embodiment.

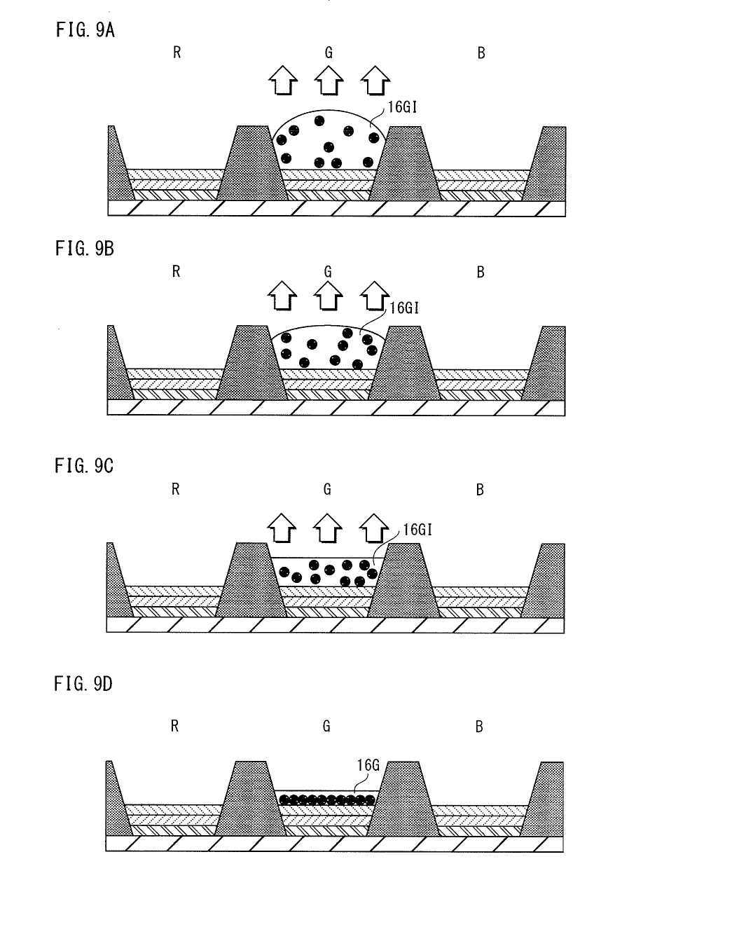

FIG. 9A to FIG. 9D show the manufacturing process of the organic EL display panel 1, and especially explain a process of forming the G light-emitting layers 16G. Arrows in FIG. 9A and FIG. 9B each represent a convection current of a solvent.

As shown in FIG. 9A, the G organic material ink 16GI, which includes a solvent in which a solute is distributed, is applied to each of the G subpixel regions. After the G organic material ink 16GI is applied, the solvent is spontaneously dried. A drying speed of the solvent differs between a central region and a periphery region in the G subpixel region. This difference in drying speed of the solvent causes a convection current where the solute moves in the solvent.

As shown in FIG. 9B, when the solvent is dried to a certain degree, the convection current is reduced and as a result the solute is difficult to move.

As shown in FIG. 9C, when the solvent is mostly dried, the convection current stops and as a result the solute stops moving. The distribution of the solute at this time is reflected to the final cross-sectional shape of the G light-emitting layers 16G.

As shown in FIG. 9D, after the solvent is completely dried, the G light-emitting layers 16G are obtained.

Here, if difference occurs in solvent atmosphere between two subpixel regions which are adjacent to a specific subpixel region on both sides thereof, a convection current having a left-right asymmetrical shape is likely to occur in the specific subpixel region. This means that the shape of a light-emitting layer in the specific subpixel region is influenced by the solvent atmosphere on the subpixel regions which are adjacent to the specific subpixel region on the both sides. For this reason, in the case where two subpixel regions on the organic EL display panel 1, which are positioned in different positions, differ from each other in terms of difference in solvent atmosphere between subpixel regions on the both sides, the organic EL display panel 1 has variation in cross-sectional shape of the light-emitting layers.

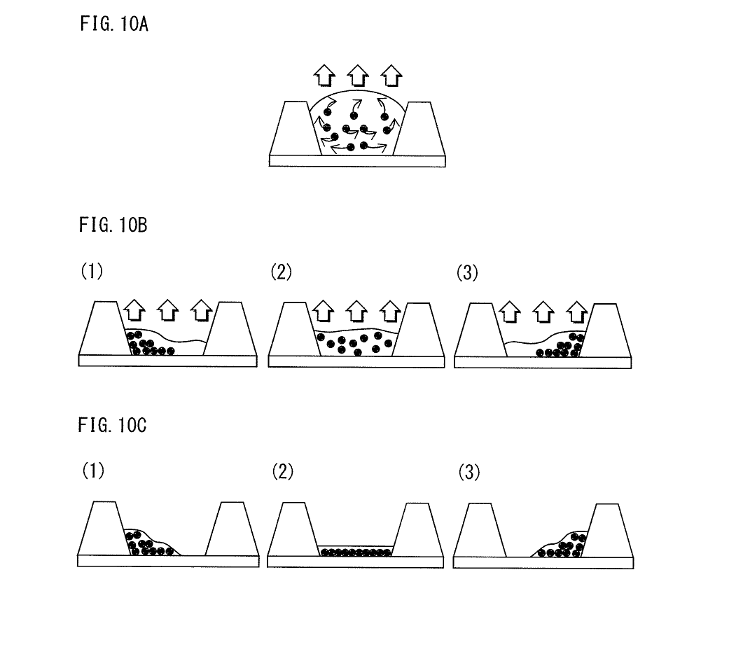

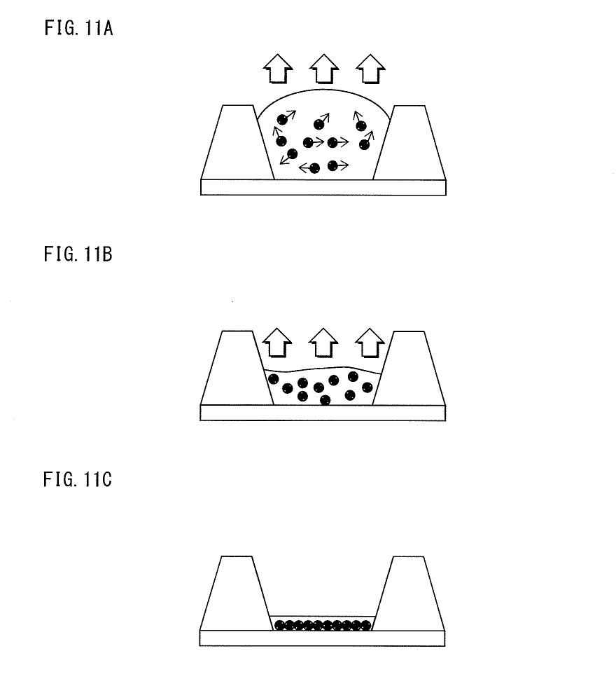

Also, the convection current of the solvent occurs differently depending on a viscosity of an organic material ink, in addition to depending on the difference in solvent atmosphere between subpixel regions on the both sides. FIG. 10A to FIG. 10C explain a manufacturing process with use of an organic material ink having a low viscosity. FIG. 11A to FIG. 11C explain a manufacturing process with use of an organic material ink having a high viscosity. Arrows in FIG. 10A and FIG. 11A each represent a convection current of a solvent.

As shown in FIG. 1 OA, when an organic material ink having a low viscosity is used, liquidity of a solvent is large. As a result, a convection current is increased, and a solute rapidly moves. As shown in sections (1) to (3) of FIG. 10B, this results in large variation in distribution of the solute at the time when the convection current stops. Specifically, a subpixel region has a distribution shown in section (1) of FIG. 10B, another subpixel region has a distribution shown in section (2) of FIG. 10B, and yet another subpixel region has a distribution shown in section (3) of FIG. 10B. Accordingly, in the case where an organic material ink having a low viscosity is applied to each of subpixel regions of a specific color, the subpixel region of the specific color is subject to an influence exercised by two subpixel regions that are adjacent to the subpixel region of the specific color on the both sides thereof, as shown in sections (1) to (3) of FIG. 10C. As a result, a prominent variation occurs in cross-sectional shape of the light-emitting layers 16 between the subpixel regions.

As shown in FIG. 11A, compared with this, when an organic material ink having a high viscosity is used, liquidity of a solvent is small. As a result, a convection current is increased, and a solute slowly moves. As shown in FIG. 11B, this results in not so large distribution of the solute at the time when the convection current stops. Accordingly, in the case where an organic material ink having a high viscosity is applied to each of subpixel regions of a specific color, the subpixel region of the specific color is not subject to an influence exercised by two subpixel regions that are adjacent to the subpixel region of the specific color on the both sides thereof, as shown in FIG. 11C. As a result, a large variation does not occur in cross-sectional shape of the light-emitting layers 16 between the subpixel regions.

In this way, the degree to which the cross-sectional shape of the light-emitting layers 16 is subject to an influence exercised by two subpixel regions on the both sides differs depending on a viscosity of an organic material ink. Accordingly, with respect to an organic material ink having the lowest viscosity, it is effective to suppress variation in difference in solvent atmosphere on the both sides between the subpixel regions which are positioned in different positions. In the present embodiment, in order to suppress variation in cross-sectional shape of the light-emitting layers 16, the application order is adjusted such that at a time when application of an organic material having a low viscosity to each of corresponding subpixel regions is started, no ink remains which has not been yet dried in two subpixel regions which are adjacent to the subpixel region on the both sides thereof.

For example, the ink application order is adjusted such that, at the start time of application of a first ink having a low viscosity to a first subpixel region, a second organic material ink and a third organic material ink which have been dried exist respectively in a second subpixel region and a third subpixel region that are adjacent to the first subpixel region on the both sides thereof. This suppresses a difference in solvent atmosphere between the second subpixel region and the third subpixel region, which are adjacent to the first subpixel region on the both sides, thereby suppressing variation in the difference in solvent atmosphere on the both sides between the first subpixel regions which are positioned in different positions, compared with the case where the organic material ink which has not been yet dried remains in only one of the second subpixel region and the third subpixel region at the start time of application of the first ink.

Also, the organic EL display panel 1 has a tendency in which a central region thereof is less subject to drying of an organic material ink which is applied than an edge region thereof. In the present embodiment, when application of the G organic material ink 16GI is started, the R organic material ink 16RI and the B organic material ink 16BI have been already dried. Accordingly, it is possible to further suppress variation in difference in solvent atmosphere on the both sides between the G subpixel regions.

Furthermore, since a time period that elapses after start of application of an organic material ink differs depending on the position of subpixel regions, a dry state of the organic material ink also differs. For example, with respect to a subpixel region to which an organic material ink has been applied earlier, spontaneous drying of the organic material ink is progressing. Accordingly, there is a comparatively small difference in solvent atmosphere between the initially applied subpixel region and a subpixel region to which an organic material ink has not been yet applied. Compared with this, with respect to a subpixel region to which the organic material ink has been comparatively recently applied, a large amount of solvent remains in the sub pixel region. Accordingly, there is a comparatively large difference in solvent atmosphere between the comparatively recently applied subpixel region and a subpixel region to which an organic material ink has not been yet applied. In the present embodiment, when application of the G organic material ink 16GI is started, the R organic material ink 16RI and the B organic material ink 16BI have been already dried. Accordingly, it is possible to further suppress variation in difference in solvent atmosphere on the both sides between the G subpixel regions.

### (5-2-2) Consideration of Drying Method

The following considers an influence on the shape of the light-emitting layer exercised by the drying method of organic material inks in addition to the application order of organic material inks.

In the present embodiment, the G organic material ink 16GI undergoes natural drying processing until the shape of the G light-emitting layer 16G has been determined, and then the G organic material ink 16GI undergoes forced drying processing. Accordingly, at the start time of forced drying processing of the G organic material ink 16GI, an amount of the solvent has been decreased to a certain degree, and the shape of the G organic material ink 16GI has been determined.

Compared with this, during a time period between start of application and completion of application, each of the R organic material ink 16RI and the B organic material ink 16BI is spontaneously dried. After completion of application, each of the R organic material ink 16RI and the B organic material ink 16BI undergoes forced drying processing.

In other words, the G organic material ink 16GI, which has a low viscosity, is longer than the R organic material ink 16RI and the B organic material ink 16BI in terms of natural drying time period after completion of application (a time period between start of application and start of forced drying processing).

The following describes reasons why there is less variation in cross-sectional shape of light-emitting layers which have undergone natural drying processing for a long natural drying time period. At a time immediately after the G organic material ink 16GI is applied, variation in shape of the G organic material ink 16GI sometimes occurs between the G subpixel regions. If this G organic material ink 16GI undergoes forced drying processing such as reduced-pressure drying processing and heated-air drying processing without undergoing sufficient natural drying processing, organic light-emitting layers 16 might be formed while there is still variation in distribution of solute. Compared with this, by securing a longer natural drying time period for the G organic material ink 16GI, which is most subject to variation in shape, than the R organic material ink 16RI and the B organic material ink 16BI, it is possible to suppress variation in distribution of solute of the applied organic material inks 16I, thereby suppressing variation in cross-sectional shape of the light-emitting layers 16.

In the present embodiment, the description has been given on the case where both the features of the application order of organic material inks and the drying method are included. Only with one of the features of the application order of organic material inks and the drying method, it is also possible to prevent variation in distribution of solute of the organic material ink at the time immediately after application from exercising an influence on the final shape of the light-emitting layers. This exhibits an effect of suppressing variation in shape of the light-emitting layers between the subpixel regions.

Note that, in the process shown in FIG. 7, the R and B organic material inks each start undergoing forced drying processing at the same time as when application thereof is completed. Alternatively, the R and B organic material inks each may undergo forced drying processing after undergoing natural drying processing for a predetermined time period. However, if the natural drying time period is secured for each of the R and B organic material inks, a long takt time occurs. For this reason, it is effective to dry the G organic material ink having the lowest viscosity for a longer drying time period than the R and B organic material inks, as described above.

### (5-3) Summary of Effects

In the present embodiment, application of the G organic material ink 16GI to each of the G subpixel regions is started at the time when application and drying of the R organic material ink 16RI and the B organic material ink 16BI are completed respectively in the R and B subpixel regions, which are adjacent to the G subpixel region on the both sides thereof. This suppresses the difference in solvent atmosphere between the R and B subpixel regions which are adjacent to each of the G subpixel regions on the both sides, thereby suppressing variation in the difference in solvent atmosphere on the both sides between the G subpixel regions, which are positioned in different positions in the organic EL display panel 1, compared with the case where an organic material ink which has not been yet dried remains in only one of the R and B subpixel regions, which are adjacent to each of the G subpixel regions, at the start time of application of the G organic material ink 16GI. This suppresses variation in cross-sectional shape of the G light-emitting layers 16G, which are positioned in different positions in the organic EL display panel 1, thereby suppressing uneven luminance.

Also, it is possible to further uniformize the film thickness of the light-emitting layers 16 in the subpixel regions.

The variation in film thickness between the subpixel regions is also caused by a material, water repellency, an inclination angle of lateral surfaces, and so on of the barrier rib layer. Accordingly, there is a case where even if there is no difference in solvent atmosphere between two subpixel regions which are adjacent to each of subpixel regions of a specific color on the both side thereof, variation occurs in film thickness of light-emitting layers 16 in the subpixel regions of the specific color. However, it is possible to uniformize the film thickness of the light-emitting layers of the specific color better in the case where a small difference in solvent atmosphere on the both sides occurs than in the case where a large difference in solvent atmosphere on the both sides occurs.

Furthermore, the G organic material ink 16GI, which has the lowest viscosity, is longer than the R organic material ink 16RI and the B organic material ink 16BI in terms of natural drying time period after completion of application (a time period between start of application and start of forced drying processing). Accordingly, it is possible to form the G light-emitting layers 16G that are positioned in different positions and have cross-sectional shapes which are most subject to variation, such that there is further less variation in cross-sectional shape.

In the present embodiment, the G organic material ink 16GI is dried by performing natural drying processing and forced drying processing. Alternatively, the G organic material ink 16GI may be dried by performing only natural drying processing without performing forced drying processing.

In the case where the organic material ink which has not been yet dried remains respectively in both the R and B subpixel regions which are adjacent to each of the G sub pixel regions on the both sides thereof at the start time of the G organic material ink to the G subpixel regions, an absolute value of difference in solvent on the both sides is smaller than that in the case where the organic material ink which has not been yet dried remains in only one of the R and B subpixel regions at the start time of the G organic material ink. This suppresses variation in the difference in solvent on the both sides between the G subpixel regions which are positioned in different positions. In other words, since the R and B organic material inks have been already applied respectively to the R and B subpixel regions at the start time of application of the G organic material ink to the G subpixel regions, it is possible to suppress variation in shape of the G light-emitting layers 16G. Note that it is not necessary to complete application of the R and B organic material inks to all the R and B subpixel regions before application of the G organic material ink is started. It is only necessary that the R and B organic material inks have been already applied to two R and B subpixel regions which are adjacent to a G subpixel region to which the G organic material ink is to be applied.

The following describes application and drying of the organic material inks other than the G organic material ink having the lowest viscosity. Application of the R and B organic material inks may be started simultaneously. Also, the R and B organic material inks may collectively undergo forced drying processing.

Furthermore, application of one of the R and B organic material inks which has a longer operating life than the other should be started earlier than the other. In the case where the R organic material ink has a longer operating life than the B organic material ink for example, application of the R, B, and G organic material inks is performed in respective orders. This suppresses variation in shape of the G light-emitting layers formed using the G organic material ink, and also maintains a further long operating life of the organic EL display panel.

Alternatively, application of one of the R and B organic material inks which has a lower viscosity than the other may be started earlier than the other. The one of the R and B organic material inks which has a lower viscosity than the other the other is more subject to variation in shape of the light-emitting layers between the subpixel regions than the other the other. In the case where application of the one of the R and B organic material inks which has a lower viscosity is started earlier than the other, no organic material ink has been yet applied on the organic EL display panel 1 at the start time of application of the one organic material ink which has a lower viscosity. Accordingly, the one organic material ink which has a lower viscosity is less subject to an influence exercised by solvent atmosphere. This suppresses variation in shape of light-emitting layers formed using the one of the R and B organic material inks which has a lower viscosity than the other, between the subpixel regions. In this case, a natural drying time period of the one of the R and B organic material inks which has a lower viscosity than the other may be set longer than a natural drying time period of the other. The natural drying time period is a time period after completion of application of the ink (stand-by time period during which the substrate is left unattended between completion of application of the ink and start of forced drying processing). As described above, it is possible to suppress variation between the subpixel regions in shape of the light-emitting layers formed using the one of the R and B organic material inks which has a lower viscosity than the other.

Moreover, application of the G organic material may be started before application of the R and B organic material inks is completed, as described in Embodiment 2 and Modifications below.

### Embodiment 2

Embodiment 2 differs from the above Embodiment 1 only in terms of the process of forming the light-emitting layers 16, and is common with Embodiment 1 in terms of configuration of the substrate and use of the ink jet. Accordingly, description on the substrate, the ink jet, and the organic material ink is omitted here.

### 1. Details of Process of Forming Light-Emitting Layers

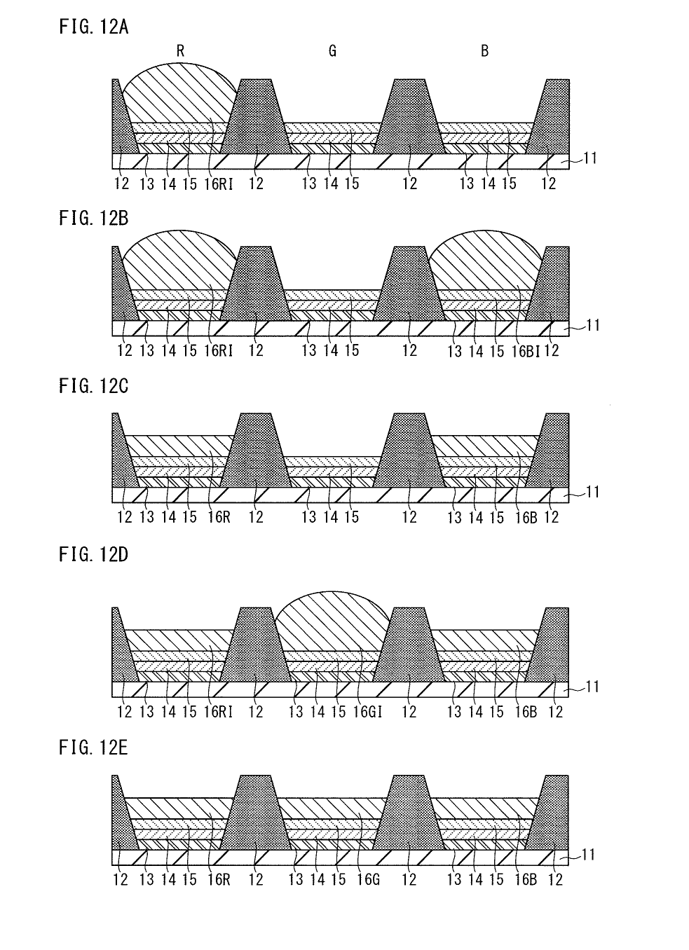

As shown in FIG. 12A, an R organic material ink 16RI is applied to each of R subpixel regions by the ink jet method.

As shown in FIG. 12B, a B organic material ink 16BI is applied to each of B subpixel regions by the ink jet method.

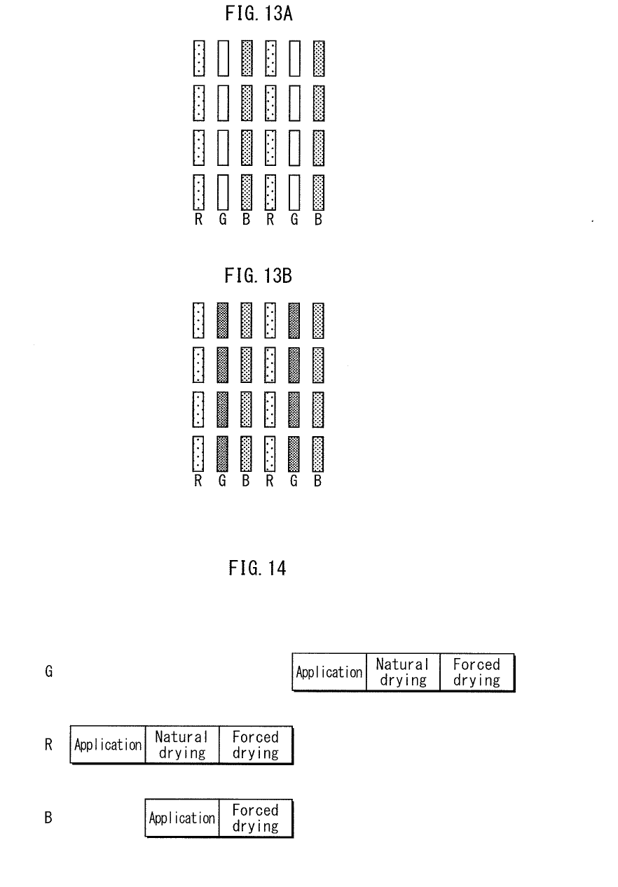

Then, as shown in FIG. 12C, R light-emitting layers 16R and B light-emitting layers 16B are formed. Specifically, the R organic material ink 16RI and the B organic material ink 16BI are applied respectively to the R and B subpixel regions on the organic EL display panel 1, and then the R organic material ink 16RI and the B organic material ink 16BI each undergo reduced-pressure drying processing at 0.5 Pa for 20 minutes. FIG. 13A is an overhead view of the state shown in FIG. 12C.

As shown in FIG. 12D, after the R light-emitting layers 16R and the B light-emitting layers 16B are formed, a G organic material ink 16GI is applied to each of G subpixel regions by the ink jet method. Since the light-emitting layers 16R and the B light-emitting layers 16B have been already formed respectively in the R and B subpixel regions which are adjacent to each of the G subpixel regions on both sides thereof, difference in solvent atmosphere on the both sides is suppressed.

Next, as shown in FIG. 12E, G light-emitting layers 16G are formed. Specifically, a stand-by time period of approximately 20 minutes to 30 minutes is given to leave the substrate unattended until solvents for all the G subpixel regions on the organic EL display panel 1 have been dried after application of the G organic material ink 16GI is completed. As a result, a G light-emitting layer 16G which has been dried only by natural drying processing is obtained in each of the G subpixel regions. FIG. 13B is an overhead view of the state shown in FIG. 12E.

Then, the entire organic EL display panel 1 undergoes bake drying processing at 130 degrees C. under N₂ atmosphere for 10 minutes. As a result, the light-emitting layers 16 are complete.

FIG. 14 is a time chart showing the manufacturing process of the organic EL display panel 1.

Firstly, the R light-emitting layers 16R and the B light-emitting layers 16B are formed respectively through application and forced drying processing of the R organic material ink 16RI and the B organic material ink 16BI. Next, the G light-emitting layers 16G are formed through application, natural dry, and forced dry by baked dry of the G organic material ink 16GI. The G organic material ink 16GI is longer than the R organic material ink 16RI in terms of natural drying time period. Note that the R organic material ink 16RI and the B organic material ink 16BI, which have a high viscosity, are less subject to variation in shape due to difference in solvent atmosphere on the both sides.

FIG. 14 shows as if the R organic material ink 16RI and the B organic material ink 16BI do not undergo forced drying processing while the G organic material ink 16GI undergoes forced drying processing. Actually, forced drying processing such as reduced-pressure drying processing and heated-air drying processing is performed on the entire organic EL panel 1. Accordingly, while the G organic material ink 16GI undergoes forced drying processing, the B organic material ink 16BI (or the B light-emitting layer 16B) and the R organic material ink 16RI (or the R light-emitting layer 16R) also undergo forced drying processing.

### 2. Effects

In this process of forming light-emitting layers, the R organic material ink 16RI and the B organic material ink 16BI simultaneously undergo forced drying processing by bake drying processing, thereby further reducing the manufacturing time period compared with that in Embodiment 1. Also, by securing a further long natural drying time period for the R organic material ink 16RI, it is possible to suppress variation in shape of the R light-emitting layers 16R which are formed using the R organic material ink 16RI.

Because of having a high viscosity, the R organic material ink 16RI and the B organic material ink 16BI collectively undergo forced drying processing after being applied to the entire organic EL display panel 1 regardless of the application order. By performing forced drying processing on the two types of organic material inks having a high viscosity at once, it is possible to further reduce the manufacturing time period compared with that in Embodiment 1.

### [Modifications]

### 1. Process of Forming Light-Emitting Layers

In the above embodiments, application of the G organic material ink is started after drying of each of the R and B organic material inks is completed. In order to further reduce an influence on the G organic material ink exercised by the difference in solvent atmosphere on the both sides, application of the G organic material ink should be desirably started after application of each of the R and B organic material inks is completed. However, the configuration is not limited to this. Alternatively, application of the G organic material ink may be started before drying of each of the R and B organic material inks is completed.

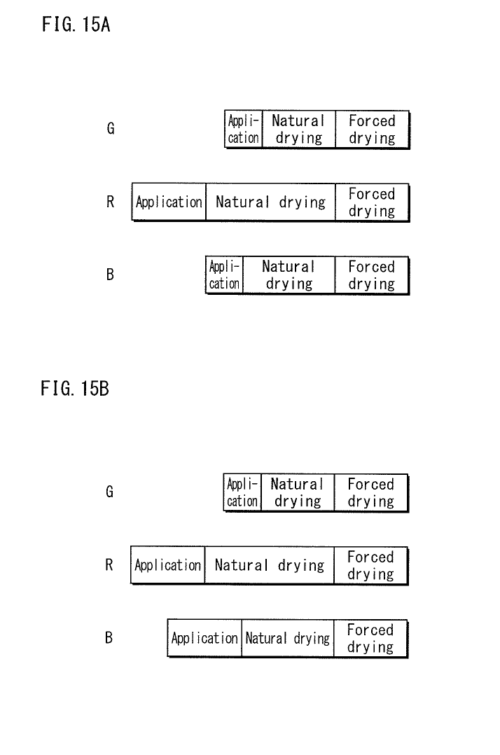

By starting application of the G organic material ink after application of each of the R and B organic material inks is started, it is possible to suppress difference in solvent atmosphere between the R and B subpixel regions which are adjacent to each of the G subpixel regions on both sides thereof, compared with the case where an organic material ink has been already applied to only one of the R and B subpixel regions (only the R organic material ink has been already applied or only the B organic material ink has been already applied) at the start time of application of the G organic material ink. As a result, it is possible to suppress variation in cross-sectional shape of the G light-emitting layers formed using the G organic material ink. The following describes, as Modification, one example of application order that is expected to exhibit effects, with reference to a time chart of the process of forming light-emitting layers shown in FIG. 15A and FIG. 15B.

At a time immediately after the G organic material ink is applied, since the solvent remains in the G subpixel regions, the G organic material ink is influenced by the difference in solvent atmosphere between the R and B subpixel regions which are adjacent to each of the G subpixel regions on the both sides thereof. Therefore, by completing application of the R and B organic material inks respectively to the R and B subpixel regions before starting application of the G organic material ink, it is possible to suppress difference in solvent atmosphere between the R and B subpixel regions on the both sides of the G subpixel region, compared with the case where an organic material ink has been already applied to only one of the R and B subpixel regions at the start time of application of the G organic material ink. This suppresses variation in the difference in solvent atmosphere on the both sides between the G subpixel regions which are positioned in different positions, thereby suppressing variation in shape of the light-emitting layers which are positioned in different positions.

For example as shown in FIG. 15A, after application of the R organic material is completed, application of the B organic material ink is started. Then, application of the G organic material ink is started before application of the B organic material ink is completed. Finally, the R, G, and B organic material inks collectively undergo forced drying processing. Since the R, G, and B organic material inks simultaneously undergo forced drying processing, it is possible to further reduce the manufacturing time period compared with that in Embodiment 1.

Also, as shown in FIG. 15B, application of the B organic material ink is started before application of the R organic material ink is completed. Then, application of the G organic material ink is started before application of the B organic material is completed. Finally, the R, G, and B organic material inks collectively undergo forced drying processing.

Also, spontaneous drying of an organic material ink starts immediately after being applied. Accordingly, in the present modification, it is preferable that spontaneous drying of the R and B organic material inks should be completed before application of the G organic material ink is started. This suppresses variation in cross-sectional shape of the G light-emitting layers between the G subpixel regions, and as a result repetition of application of organic material inks further reduces the manufacturing time period.

### 2. Properties of Organic Material Ink

### (Viscosity)

The above embodiments have given the description that the G organic material ink includes an organic light-emitting material that has the lowest viscosity among R, G, and B organic light-emitting materials. Alternatively, the B or R organic light-emitting material may have the lowest viscosity.

For example, it is preferable that in the case where the B organic material ink has a lower viscosity than the R and G organic material inks, application of the B organic material ink should be started before application of the R and G organic material inks is started.

Also, an organic material ink for use in the device structure by the inkjet method should have a viscosity of 5 mPas to 50 mPas. Here, a high viscosity of organic material inks in the present invention falls in a range of approximately 9 mPas to 15 m Pas. Also, a low viscosity of organic material inks in the present invention falls in a range of approximately 4 mPas to 7 mPas.

Furthermore, even if more than three types of organic material inks are used, it is possible to exhibit the same effects as those in the above embodiments, by starting application with an organic material ink having the lowest viscosity among the more than three types of organic material inks in the same manner as in the above embodiments.

(Surface Tension) The organic material ink should preferably have a surface tension of 20 mN/m to 70 mN/m, and should particularly preferably have a surface tension of 25 mN/m to 45 mN/m. By setting the surface tension of the organic material ink in this range, it is possible to prevent a so-called flight curve of droplets of the organic material ink during discharge. Specifically, in the case where the organic material ink has a surface tension of less than 20 mN/m, the organic material ink has an increased wettability on a surface of the nozzle. As a result, when the organic material ink is discharged, the organic material ink might attach asymmetrically around a nozzle hole. In this case, since an attractive force occurs between part of the organic material ink which attaches the nozzle hole and part of the organic material ink which is to be discharged, the organic material ink is discharged by non-uniform force. As a result, a flight curve often occurs and the organic material ink cannot reach a target position. On the contrary, in the case where the organic material ink has a surface tension of more than 70 mN/m, the shape of droplets at the front end of the nozzle is unstable. This results in difficulty controlling the discharge diameter and discharge timing of the organic material ink.

### (Solids Concentration)

The organic material ink should preferably have a solid content concentration of 0.01 wt % to 10.0 wt % and more preferably 0.1 wt % to 5.0 wt % relative to all compositions. If the organic material ink has a too low solid content concentration, many times of discharges are required for obtaining a necessary film thickness. This deteriorates manufacturing efficiency. On the contrary, if the organic material ink has a too high solid content concentration, the organic material ink has an increased viscosity. This exercises an influence on discharge properties.

### (Solvent)

Generally, an organic material for layers having a light-emitting function such as light-emitting layers and hole injection layers in the present invention is dissolved in an organic solvent so as to be converted to an organic material ink for application. A solvent for the organic material is selected in consideration of solubility and stability of the organic material, viscosity and surface tension of an organic material ink which are necessary for forming light-emitting layers, a boiling temperature which is necessary for securing uniformity of the light-emitting layers, and so on.

The solvent for the organic material ink may range from a solvent having a comparatively low boiling temperature such as toluene and xylene to a solvent having a boiling temperature of more than 300 degrees C. such as dodecylbenzene.

For example, a hydrocarbon solvent or an aromatic solvent may be used, such as n-dodecylbenzene, n-decylebenzene, isopropylbiphenyl, 3-ethylbiphenylnonylbenzene, 3-methylbiphenyl, 2-isopropylnaphthalene, 1,2-dimethylnaphthalene, 1,4-dimethylnaphthalene, 1,6-dimethylnaphthalene, 1,3-diphenylpropane, diphenylmetan, octylbenzene, 1,3-dimethylnaphthalene, 1-ethylnaphthalene, 2-ethylnaphthalene, 2,2′-dimethylbiphenyl, 3,3′-dimethylbiphenyl, 2-methylbiphenyl, 1-methylnaphthalene, 2-methylnaphthalene, cyclohexylbenzene, 1,3,5-triisopropylbenzene, hexylbenzene, 1,4-diisopropylbenzene, tetralin, 1,3-diisopropylbenzene, 5-tert-butyl-m-xylene, amylbenzene, 1,2,3,5-tetramethylbenzene, 5-isopropyl-m-xylene, 3,5-dimethylanisole, 4-ethyl-m-xylene, n-butylbenzene, methoxytoluene, seG-butylbenzene, isobutylbenzene, 1,2,4-trimethylbenzene, tert-butylbenzene, 1,3,5-trimethylbenzene, anisole, dibutyl phthalate, dihexyl phthalate, dicyclohexylketone, cyclopentylphenylketone, diethyl phthalate, dimethyl phthalate, hexylbenzoate, isoamylbenzoate, n-buthylbenzoate, 2-cyclohexylcyclohexanone, 2-n-heptylcyclopentanone, phenoxytoluene, diphenylether, 1-ethoxynaphthalene, 2-methoxybiphenyl, isobutylbenzoate, propylbenzoate, isovaleric acid cyclohexyl ester, ethylbenzoate, cyclopropylphenylketone, 2-hexylcyclopentanone, 2-pyrrolidone, 2-cyclopentylcyclopentanone, 1-methyl-2-pyrrolidone, 6-methoxy-1,2,3,4-tetrahydronaphthalene, 2,5-dimethoxytoluene, 1-methoxy-2,3,5-trimethylbenzene, butylphenylether, 3,4-dimethylanisole, methylbenzoate, and 4-ethylcyclohexanone. Alternatively, monohydric alcohol such as methanol, ethanol, isopropyl alcohol, and n-butanol, or a cellosolve solvent such as methylcellosolve and ethylcellosolve may be used. Further alternatively, in consideration of solubility and so on of materials, other solvent may be used.

Furthermore, though only one type of these solvents may be used, these solvents should preferably be used in mixture. Here, by using a solvent having a comparative low boiling temperature in mixture with a solvent having a high boiling temperature, it is possible to increase planarity of light-emitting layers after the solvent has been dried. For example, in the case where a solvent having a boiling temperature of 100 degrees C. to 200 degrees C. is used in mixture with a solvent having a boiling temperature of 250 degrees C. to 350 degrees C., light-emitting layers having an excellent planarity are obtained by the inkjet method and the nozzle-coat method.

### 3. Ink Jet Head

Since a piezo ink jet head discharges an ink by deforming piezo elements. For this reason, the use of an ink having a too high viscosity deteriorates discharge properties, thereby deteriorating landing accuracy. Accordingly, it is necessary to consider the performance of the piezo ink jet head in use of an ink having a high viscosity.

Also, in the above embodiments and so on, the multipath printing method is used according to which printing is performed by plural times of ink jet head scanning. Alternatively, a method such as a line bank method may be used according to which printing is performed by a single time of ink jet head scanning.

### 4. Printing Method

The printing method of organic material inks applicable to the present invention is not limited to the ink jet method. Alternatively, a gravure printing method may be applicable to the present invention.

### 5. Drying Method

It is important that how an organic material ink is dried from a viewpoint of suppressing variation in cross-sectional shape of light-emitting layers. An organic material ink is dried by a drying method such as vacuum drying processing, heated-air drying processing, or drying processing inert gas. Also, there is a case where an organic material ink is dried under an atmosphere filled with a certain amount of a solvent for the organic material ink.

### 6. Layer Configuration

The organic EL display panel 1 may be of a so-called top emission type in which light emitted from light-emitting layers is extracted from the opposite side of a glass substrate or a so-called bottom emission type in which light emitted from the light-emitting layers is extracted from the side of the glass substrate. In the case where the organic EL display panel 1 is of the bottom emission type, anodes that are substantially translucent and a light-reflective cathode should preferably be used. The anodes and the cathode often each have a multi-layer structure. Furthermore, the organic EL display panel 1 may have a so-called reverse structure in which one of two types of electrodes that is provided close to the substrate is used as a cathode. The effects of the present invention are expected to be exhibited by both of the bottom emission type with the reverse structure and the top emission type with the reverse structure.

### 7. Light-Emitting Layers and IL Layers

Light emitting layers are formed on hole injection layers by applying an organic semiconductor material. Also, an electron injection layer is formed between each of the light-emitting layers and a cathode. From a viewpoint of light-emitting efficiency, it is preferable that an IL layer should be provided as a hole blocking layer between each of the light-emitting layers and each of the hole injection layers. The hole blocking layer is made of a polyfluorene high-polymer material such as TFB that has a higher LUMO (lowest unoccupied molecular orbital) or a lower electron mobility than the material of the light-emitting layers. However, the configuration of the hole blocking layer is not limited to this. Also, the light-emitting layers may be made of any type of polyfluorene materials, polyphenylenevinylene materials, and low molecular materials such as pendant, dendrimer, and coating-type materials, as long as the material is dissolved in a solvent and applied to form a thin film.

The light-emitting layers may be made of a plurality of types of materials having a light-emitting function, such that mobility and injection properties of holes and electrons and luminescent chromaticity are adjusted. Also, in the case where a light-emitting material is used as a dopant, an application liquid resulting from mixing a host material with a dopant may be used. The dopant may be known fluorescent light-emitting material or phosphorescent light-emitting material. These materials each may be low molecular, high molecular, oligomer, or the like. Furthermore, these materials may be variously combined with each other. For example, a low molecular dopant may be added to a high molecular host material.

### 8. Barrier Rib Layer and Bank

A barrier rib layer should desirably have a thickness of 100 nm or greater, though largely depending on a concentration of an organic material ink for printing. Also, the barrier rib layer may be arbitrarily made of any material having electrical insulating properties. Specifically, the barrier rib layer should preferably be made of resin having electrical insulating properties and resistance properties against heat and solvent, such as polyimide resin. Furthermore, it is desirable that the barrier rib layer should have a function of preventing overflow of an organic material ink at the time of printing in regions separated by a bank by an ink jet or the like, by including a component that is repellent to an organic material ink in an organic material of the barrier rib layer. The barrier rib layer is formed by patterning with use of a photolithography technology or the like. For example, after a material of the barrier rib layer is applied, the barrier rib layer with a desired shape is formed on a TFT substrate through base processing, mask exposure processing, development processing, and so on. Moreover, the barrier rib layer in the above embodiments has a forward tapered cross section. This forward tapered shape is preferable in terms of that overflow of an organic material ink is prevented and that a formation state of light-emitting layers is checked. However, the cross-sectional shape of the barrier rib layer is not limited to the forward tapered shape.

### 9. Hole Injection Layers

Hole injection layers are made of an organic material such as polythiophene PEDT:PSS by a spin-coat method, the inkjet method, or the nozzle-coat method. Alternatively, the hole injection layers may be made of polyaniline material. Further alternatively, it is known that the hole injection layers are made of an inorganic material, and may be made of molybdenum oxide, tungsten oxide, vanadium oxide, ruthenium oxide, or the like. Yet alternatively, the hole injection layers may be formed by evaporating a carbon compound such as fullerene, molybdenum oxide, and tungsten oxide, with use of the vacuum evaporation method, an electron beam evaporation method, a sputtering method, or the like.

The hole injection layer should preferably be made of in particular transition metal oxide material because of having high inonization potential, ease of injecting holes to a light-emitting material, and high stability. By forming the hole injection layers from these oxide materials such that the hole injection layers have a defect level at the time of or after formation, it is effective to increase the hole injection properties of the hole injection layers. Also, the hole injection layers should preferably have a film thickness of 5 nm to 200 nm.

### 10. Cathode

A cathode is made of metal or alloy having a low work function. In the above embodiments, in the case of an organic EL display panel of the top emission type, a transparent cathode should be formed by forming an extremely thin film having high light transmissivity from metal having low work function, and laminating a conductive film that is made of a translucent material such as ITO and IZO on the extremely thin film. The extremely thin film, which is made of metal having low work function, is not limited to having a two-layer structure of Ba and AI, and may have a two-layer structure of Ca and AI. Alternatively, the extremely thin film may be made of metal such as Li, Ce, Ca, Ba, In, Mg, and Ti, or metal oxide of any of these metals, halide typified by fluoride, Mg alloy such as Mg—Ag alloy and Mg—In alloy, and AI alloy such as AI—Li alloy, AI—Sr alloy, and AI-Ba alloy. Alternatively, a cathode should preferably made of an extremely thin film having a laminated structure of a combination of LiO2 and AI, a combination of LiF and AI, or the like and a translucent conductive film that is laminated on the extremely thin film. Furthermore, an electron injection layer may be made of transition metal oxide material having oxygen deficiency and conductivity such as TiOx, MoOx, WOx, TiOx, and ZnO.

### 11. Electrical Connection of Organic EL Display Panel

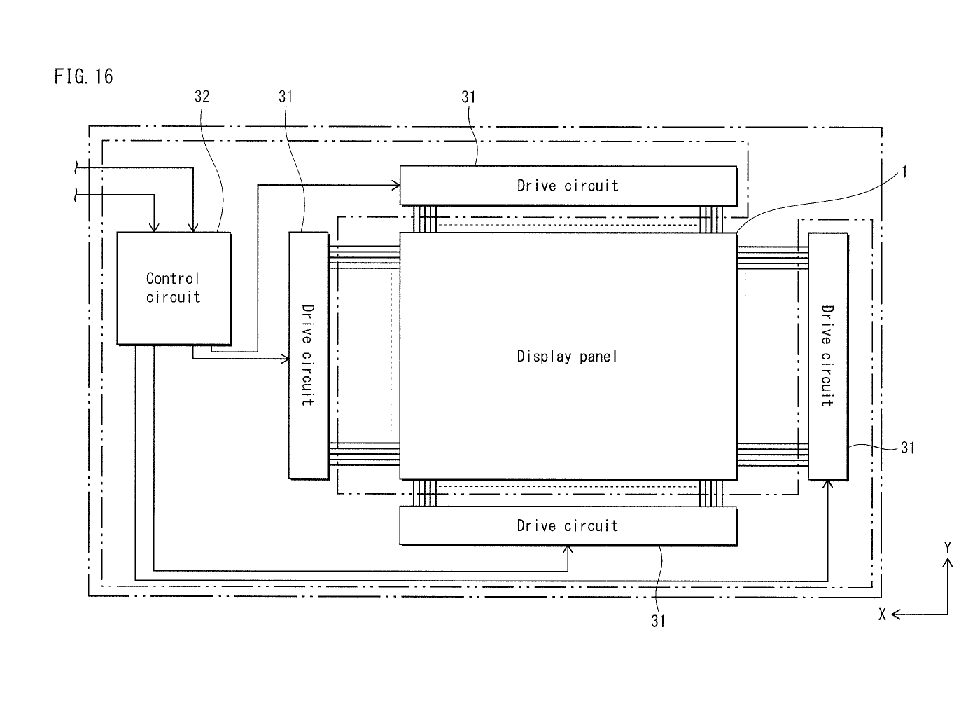

As shown in FIG. 16, the organic EL display panel relating to the above embodiments is connected to drive circuits 31 that are controlled by a control circuit 32.

### 12. Product Form

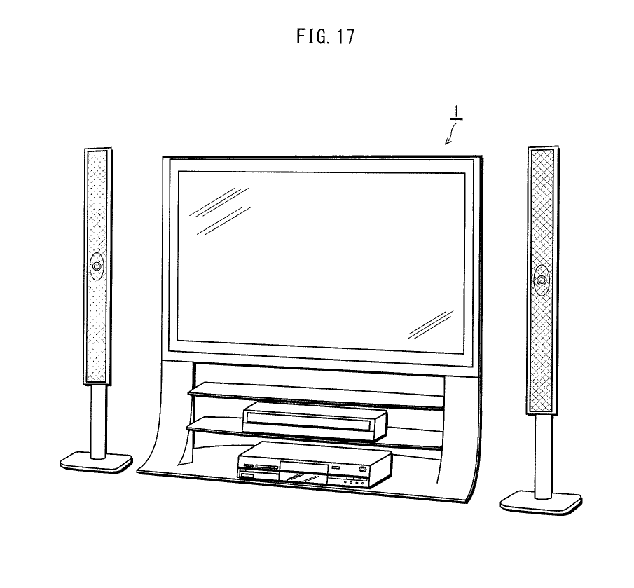

It is possible to distribute the organic EL display panel relating to the above embodiments as a single device to a market channel. In addition, without being limited to distribution as a single device, the organic EL display panel may be distributed by being incorporated into a display device such as a digital television as shown in FIG. 17.

### INDUSTRIAL APPLICABILITY

In manufacturing of organic EL display panels including organic EL elements formed by an ink jet device, the present invention suppresses uneven luminance that occurs in the organic EL display panels due to the use of an ink having a low viscosity. The present invention provides an organic EL display panel having a high image quality with no uneven luminance caused by a viscosity of an ink material or the like, and therefore exhibits high versatility and availability in the field of displays for various types of electronic appliances.

### REFERENCE SIGNS LIST

1 organic EL display panel
11 TFT substrate
12 barrier rib layer
13 anode
14 hole injection layer
15 IL layer
16 light-emitting layer
16R R light-emitting layer
16G G light-emitting layer
16B B light-emitting layer
16I organic material ink
16RI R organic material ink
16GI G organic material ink
16BI B organic material ink
17 electron injection layer
18 cathode
19 sealing layer
20 ink jet head
31 drive circuit
32 control circuit

1-10. (canceled)

11. A manufacturing method of an organic EL display panel comprising:
preparing a first ink including a first organic light-emitting material and a solvent;
preparing a second ink including a second organic light-emitting material and a solvent, the second organic light-emitting material differing from the first organic light-emitting material in terms of light-emitting wavelength;
preparing a third ink including a third organic light-emitting material and a solvent, the third organic light-emitting material differing from the first organic light-emitting material and the second organic light-emitting material in terms of light-emitting wavelength;
applying the first ink to first subpixel regions on a substrate;
applying the second ink to second subpixel regions that are each adjacent to a corresponding one of the first subpixel regions; and
applying the third ink to third subpixel regions that are each adjacent to a corresponding one of the first subpixel regions on an opposite side of the first subpixel region relative to a corresponding one of the second subpixel regions, wherein
the first ink has a lower viscosity than the second ink and the third ink, and
after application of the second ink and the third ink is started, application of the first ink is started.

12. The manufacturing method of claim 11, further comprising:
drying the second ink, after the applying the second ink; and
drying the third ink, after the applying the third ink, wherein
after drying of the second ink and the third ink is started, application of the first ink is started.

13. The manufacturing method of claim 11, further comprising:
drying the second ink, after the applying the second ink; and
drying the third ink, after the applying the third ink, wherein
after drying of the second ink and the third ink is completed, application of the first ink is started.

14. The manufacturing method of claim 11, further comprising:
drying the first ink through forced drying processing, after the applying the first ink;
drying the second ink through forced drying processing, after the applying the second ink; and
drying the third ink through forced drying processing, after the applying the third ink, wherein
a natural drying time period of the first ink is longer than a natural drying time period of each of the second ink and the third ink, the natural drying time period being a time period from when application is completed to when forced drying processing is started.

15. The manufacturing method of claim 11, wherein
after application of the second ink and the third ink is completed, application of the first ink is started, and
after application of the first ink is completed, drying of the first ink, the second ink, and the third ink is collectively performed through forced drying processing.

16. The manufacturing method of claim 13, further comprising:
drying the second ink through forced drying processing, after the applying the second ink; and
drying the third ink through forced drying processing, after the applying the third ink, wherein
after drying of the second ink and the third ink is completed, application of the first ink is started.

17. The manufacturing method of claim 11, further comprising
drying the first ink through natural drying processing, after the applying the first ink.

18. The manufacturing method of claim 11, wherein
application of one of the second ink and the third ink that has a longer operating life than the other is started earlier than the other.

19. The manufacturing method of claim 11, wherein
application of one of the second ink and the third ink that has a lower viscosity than the other is started earlier than the other.

20. The manufacturing method of claim 19, wherein
a natural drying time period of the one of the second ink and the third ink that has a lower viscosity than the other is longer than a natural drying time period of the other, the natural drying time period being a time period from when application is completed to when forced drying processing is started.
